(19) United States
(12) Patent Application Publication
(10) Pub. No.: US 2024/0276694 A1
(43) Pub. Date: Aug. 15, 2024

(54) CONTROL DEVICE AND METHOD FOR SUPPLYING POWER TO FEEDER

(71) Applicant: FUJI CORPORATION, Chiryu (JP)

(72) Inventors: Motoki TANAKA, Chiryu-shi (JP); Shingo FUJIMURA, Toyoake-shi (JP)

(73) Assignee: FUJI CORPORATION, Chiryu (JP)

(21) Appl. No.: 18/559,652

(22) PCT Filed: Jun. 11, 2021
(86) PCT No.: PCT/JP2021/022275

§ 371 Date: Nov. 8, 2023

(51) Int. Cl. H05K 13/04; H05K 13/08

(52) U.S. Cl. CPC H05K 13/0419; H05K 13/0882

(57) ABSTRACT

A control device and method for supplying power to feeders inserted from multiple slots each of which includes an indicator lamp and into which the feeders are inserted, the method including a feeder insertion position indication step of turning on an indicator lamp of a slot to which the power is supplied, a feeder insertion step of inserting the feeder into the slot to which the power is supplied and of which the indicator lamp is turned on in the feeder insertion position indication step, and a power supply check step of, in a case where the feeder inserted in the feeder insertion step is a normal feeder, turning off the indicator lamp of the slot to which the power is supplied, the indicator lamp being turned on by supplying the power to the inserted feeder.

### TECHNICAL FIELD

The present disclosure relates to a control device that supplies power to a slot into which a feeder is inserted, and a method for supplying power to the feeder from the slot.

### BACKGROUND ART

Patent Literatures described below describe techniques related to a slot into which a feeder is inserted.

### PATENT LITERATURE

Patent Literature 1: JP-A-2004-134676
Patent Literature 2: WO 2004/86839

### BRIEF SUMMARY

### Technical Problem

In the present description, an object of the present disclosure is to improve practicability of power supply in a slot into which a feeder is inserted.

### Solution to Problem

In order to solve the object described above, the present description discloses a control device configured to supply power to multiple slots each of which includes an indicator lamp and into which feeders are inserted, and to turn on the indicator lamp of the slot to which the power is supplied.

In order to solve the object described above, the present description discloses a method for supplying power to feeders inserted from multiple slots each of which includes an indicator lamp and into which the feeders are inserted, the method including a feeder insertion position indication step of turning on an indicator lamp of a slot to which the power is supplied, a feeder insertion step of inserting the feeder into the slot to which the power is supplied and of which the indicator lamp is turned on in the feeder insertion position indication step, and a power supply check step of, in a case where the feeder inserted in the feeder insertion step is a normal feeder, turning off the indicator lamp of the slot to which the power is supplied, the indicator lamp being turned on by supplying the power to the inserted feeder.

### Advantageous Effects

According to the present disclosure, by turning on the indicator lamp of the slot to which the power is supplied, the practicability of the power supply in the slot into which the feeder is inserted is improved.

### BRIEF DESCRIPTION OF DRAWINGS

FIG. 1 is a perspective view illustrating an electric component mounting device.

FIG. 2 is a plan view illustrating a taped component.

FIG. 3 is a schematic view illustrating a tape feeder.

FIG. 4 is a perspective view illustrating a tape feeder rack.

FIG. 5 is a schematic view illustrating the tape feeder rack in a state where LED at an accommodation position of the tape feeder is turned on.

FIG. 6 is a schematic view illustrating the tape feeder rack in a state where the tape feeder is accommodated at the accommodation position at which LED is turned on.

FIG. 7 is a schematic view illustrating the tape feeder rack in a state where LED at the accommodation position at which the tape feeder is accommodated is turned off.

FIG. 8 is a schematic view illustrating the tape feeder rack in a state where LED at the accommodation position at which the tape feeder to be extracted is accommodated is turned on.

### DESCRIPTION OF EMBODIMENTS

Hereinafter, as an embodiment of the present disclosure, an example of the present disclosure will be described in detail with reference to drawings.

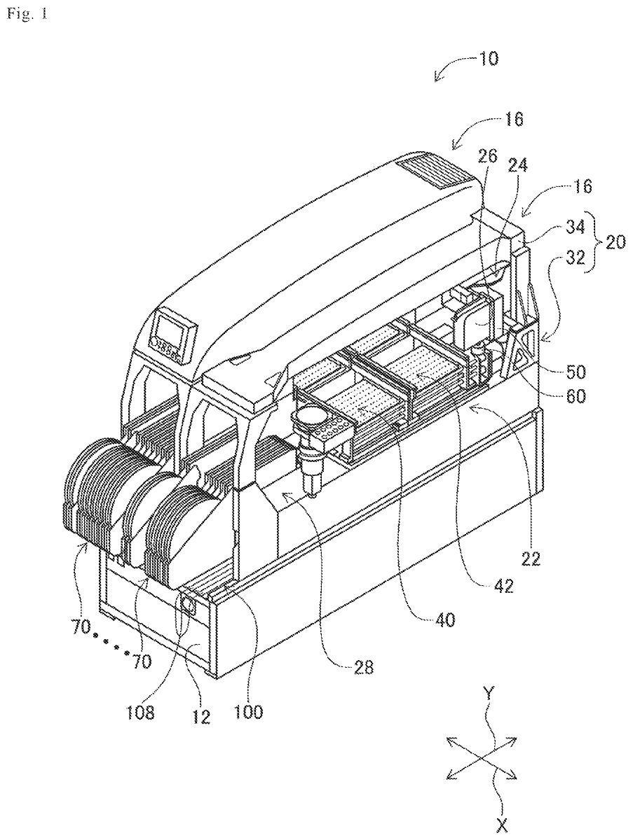

FIG. 1 illustrates electric component mounting device (hereinafter, sometimes abbreviated as “mounting device”) 10. Mounting device 10 includes one system base 12, and two component mounters (hereinafter, sometimes abbreviated as “mounter”) 16 that are adjacent to each other on system base 12. A direction in which mounters 16 are arranged will be referred to as an X-axis direction, and a horizontal direction perpendicular to the X-axis direction will be referred to as a Y-axis direction.

Each mounter 16 mainly includes mounter main body 20, conveyance device 22, mounting head moving device (hereinafter, sometimes abbreviated as “moving device”) 24, mounting head 26, and supply device 28. Mounter main body 20 includes frame 32 and beam 34 suspended on frame 32.

Conveyance device 22 includes two conveyor devices 40 and 42. Two conveyor devices 40 and 42 are disposed on frame 32 to be parallel to each other and to extend in the X-axis direction. Each of two conveyor devices 40 and 42 conveys a circuit board, which is supported at each of conveyor devices 40 and 42 in the X-axis direction, by an electromagnetic motor (not illustrated). The circuit board is fixedly held at a predetermined position by a board holding device (not illustrated).

Moving device 24 is an XY robot type moving device. Moving device 24 includes an electromagnetic motor (not illustrated) that slides slider 50 in the X-axis direction, and an electromagnetic motor (not illustrated) that slides slider 50 in the Y-axis direction. Mounting head 26 is attached to slider 50, and mounting head 26 is moved to any position on frame 32 due to the operations of two electromagnetic motors.

Mounting head 26 mounts an electronic component on the circuit board. Suction nozzle 60 is provided on a lower end surface of mounting head 26. Suction nozzle 60 communicates with positive and negative pressure supply device (not illustrated) through positive pressure air and negative pressure air passages. Suction nozzle 60 picks up and holds the electronic component by using a negative pressure, and separates the held electronic component by using a positive pressure. Mounting head 26 includes a nozzle lifting and lowering device (not illustrated) that lifts and lowers suction nozzle 60. The nozzle lifting and lowering device changes a position of the electronic component held by mounting head 26 in an up-down direction.

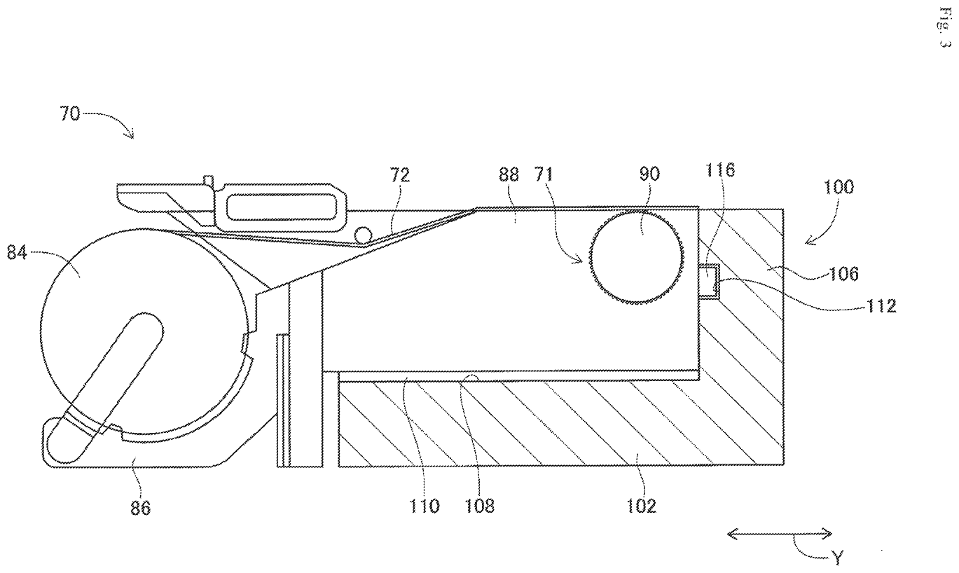

Supply device 28 is a feeder type supply device, and is disposed at a front end part of frame 32. Supply device 28 includes tape feeder 70. Tape feeder 70 accommodates a taped component, which is a tape accommodating the electronic components, in a wound state. Tape feeder 70 feeds the taped component by an operation of feeding device (see FIG. 3) 71. As a result, feeder type supply device 28 supplies the electronic component at a supply position by feeding the taped component.

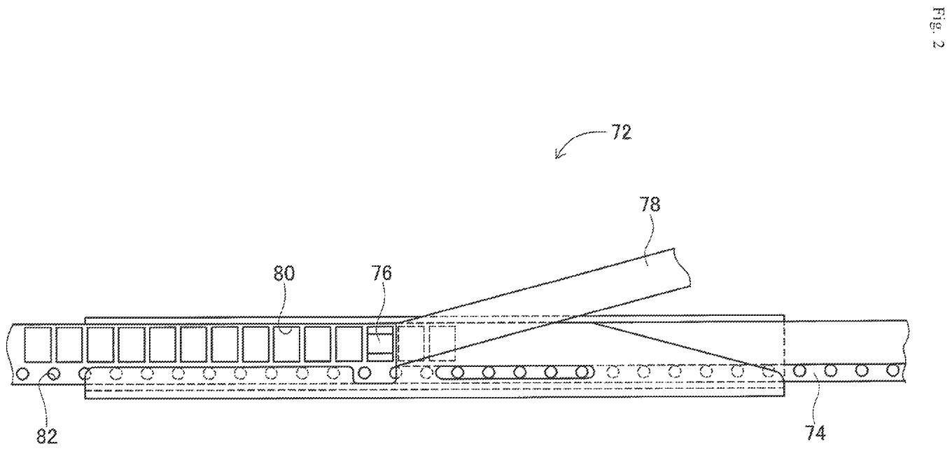

Specifically, as illustrated in FIG. 2, taped component 72 includes carrier tape 74, electronic component 76, and top cover tape 78. In carrier tape 74, large number of accommodation recessed portions 80 and feed holes 82 are formed at equal pitches, and electronic components 76 are accommodated in accommodation recessed portions 80. Accommodation recessed portion 80 accommodating electronic component 76 is covered with top cover tape 78.

As illustrated in FIG. 3, tape feeder 70 includes reel holder 86 and feeder main body 88, and tape reel 84 is attached to tape feeder 70. Taped component 72 is wound, and reel holder 86 holds tape reel 84. Taped component 72 is pulled out from tape reel 84 held by reel holder 86, and taped component 72 extends to an upper end surface of feeder main body 88. A longitudinal direction of the tape feeder, that is, a longitudinal direction of slide groove 108 described later is a tape feeding direction.

Sprocket 90 is built in feeder main body 88 and is engaged with feed hole 82 formed in taped component 72. When sprocket 90 is rotated by the operation of feeding device 71, taped component 72 is fed in a direction separating from tape reel 84 on the upper end surface of feeder main body 88. Further, top cover tape 78 is peeled off from carrier tape 74 of taped component 72 by a peeling device (not illustrated). As a result, accommodation recessed portions 80 of taped component 72 are sequentially opened at a distal end of the upper end surface of feeder main body 88, and electronic component 76 is extracted by suction nozzle 60 from opened accommodation recessed portions 80.

Tape feeder 70 is detachably provided on tape feeder holding table 100 fixedly provided at the front end part of frame 32. Specifically, tape feeder holding table 100 includes holding table base 102 provided on the upper surface of frame 32 and holding table side frame 106 erected on an end of holding table base 102 on a side close to conveyance device 22. Multiple slide grooves 108 are formed in holding table base 102 to extend in the Y-axis direction. Rail 110 is attached to a lower edge part of feeder main body 88 of tape feeder 70. By fitting rail 110 into slide groove 108, tape feeder 70 can be linearly slid on an upper surface of holding table base 102 in a direction approaching and separating from holding table side frame 106.

Holding table side frame 106 is provided with connection terminal 112. Connector 116 is provided on a side wall surface of tape feeder 70 on a side opposite to reel holder 86. Then, when an operator fits rail 110 of tape feeder 70 into slide groove 108 of tape feeder holding table 100 and slides tape feeder 70 in a direction approaching holding table side frame 106, connector 116 is connected to connection terminal 112.

In this way, tape feeder 70 is positioned and mounted on tape feeder holding table 100. When the operator slides tape feeder 70 mounted on tape feeder holding table 100 in a direction separating from holding table side frame 106, connected connector 116 is detached from connection terminal 112, and tape feeder 70 is detached from tape feeder holding table 100. In this manner, tape feeder 70 is detachably positioned and mounted on tape feeder holding table 100 by the operator without using a tool. As illustrated in FIG. 1, multiple slide grooves 108 are formed in tape feeder holding table 100, and tape feeder 70 is mounted in any slide groove 108 among multiple slide grooves 108.

Tape feeder 70 mounted on tape feeder holding table 100 is electrically connected to mounter 16 by connecting connector 116 to connection terminal 112. As a result, power is supplied to tape feeder 70, and operations of feeding device 71, the peeling device, and the like are controlled, so that tape feeder 70 supplies electronic component 76 at the supply position. The power is always supplied to tape feeder 70 mounted on tape feeder holding table 100, and electronic component 76 is supplied at any timing.

In mounter 16, with the configuration described above, mounting head 26 executes a mounting operation on the circuit board held by conveyance device 22. Specifically, the circuit board is conveyed to an operation position and fixedly held at the operation position. Tape feeder 70 feeds taped component 72 and supplies electronic component 76 at the supply position. Then, mounting head 26 is moved above the supply position of electronic component 76, and picks up and holds electronic component 76 by suction nozzle 60. Subsequently, mounting head 26 is moved above the circuit board, and mounts the held electronic component on the circuit board.

In this way, in mounter 16, electronic component 76 supplied from tape feeder 70 is mounted on the circuit board. Since multiple types of electronic components are mounted on the circuit board, multiple tape feeders 70 are mounted on tape feeder holding table 100 of mounter 16, and some of multiple tape feeders 70 accommodate different types of taped components 72. As a result, multiple types of electronic components are supplied from multiple tape feeders 70 mounted on tape feeder holding table 100, and multiple types of electronic components are mounted on the circuit board.

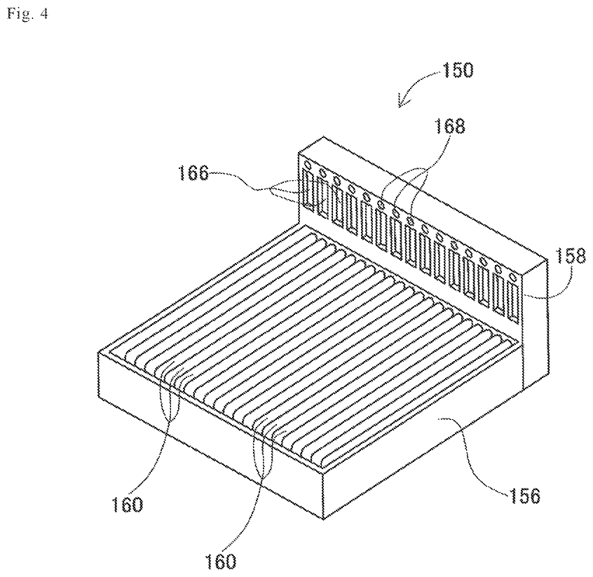

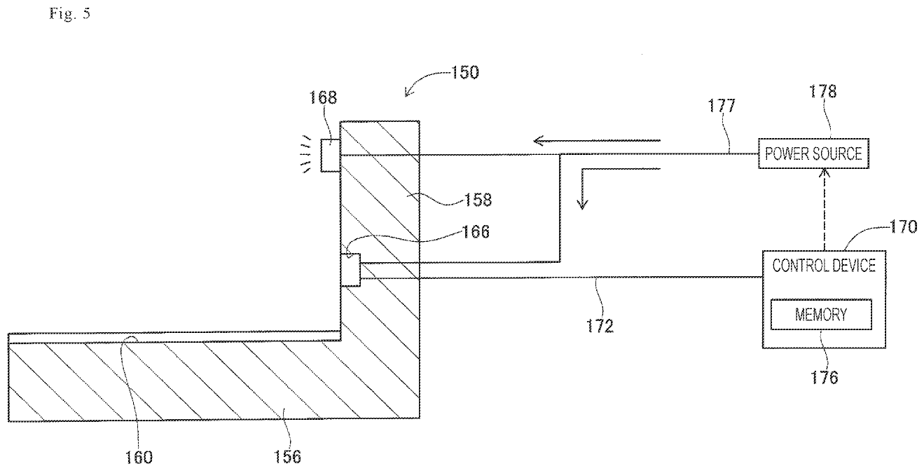

As described above, it is necessary to mount multiple tape feeders 70 accommodating different types of taped components 72 on tape feeder holding table 100 of mounter 16. Therefore, multiple tape feeders 70 that can be mounted on tape feeder holding table 100 of mounter 16 are accommodated in tape feeder rack 150 that is installed separately from mounter 16 illustrated in FIG. 4, and information related to the type of electronic component accommodated in the tape reel attached to each of multiple tape feeders 70 is managed by control device (see FIG. 5) 170 described later.

Specifically, tape feeder rack 150 includes rack base 156 and rack side frame 158 erected on an end of rack base 156. Multiple slide grooves 160 are formed in rack base 156 to extend from an end at which rack side frame 158 is erected toward an end opposite to the end. Each of multiple slide grooves 160 has the same shape as slide groove 108 of tape feeder holding table 100. Therefore, by fitting rail 110 of tape feeder 70 into each of multiple slide grooves 160 of tape feeder rack 150, tape feeder 70 can be linearly slid on an upper surface of rack base 156 in a direction approaching and separating from rack side frame 158.

Rack side frame 158 is provided with multiple connection terminals 166 corresponding to multiple slide grooves 160. Each of multiple connection terminals 166 has the same shape as connection terminal 112 of tape feeder holding table 100. Therefore, when the operator fits rail 110 of tape feeder 70 into slide groove 160 of tape feeder rack 150 and slides tape feeder 70 in a direction approaching rack side frame 158, whereby connector 116 is connected to connection terminal 166. In this way, tape feeder 70 is positioned and accommodated in tape feeder rack 150. When the operator slides tape feeder 70 accommodated in tape feeder rack 150 in a direction separating from rack side frame 158, tape feeder 70 is detached from tape feeder rack 150. In this manner, tape feeder 70 is detachably positioned and accommodated in tape feeder rack 150 by the operator without using a tool. In rack side frame 158, multiple LEDs 168 are disposed each corresponding to multiple slide grooves 160 above multiple connection terminals 166.

As illustrated in FIG. 5, tape feeder rack 150 is connected to control device 170, and each of multiple connection terminals 166 of tape feeder rack 150 is connected to control device 170 by communication cable 172. Memory 176 is built in control device 170. Connection terminal 166 and LED 168 disposed corresponding to each of multiple slide grooves 160 of tape feeder rack 150 are connected to power source 178 through power supply cable 177. A first end of power supply cable 177 is bifurcated, the bifurcated first end of power supply cable 177 is connected to LED 168 and connection terminal 166 disposed corresponding to each of multiple slide grooves 160, and second end of power supply cable 177 is connected to power source 178. Power source 178 supplies the power to connection terminal 166 and LED 168 or cuts off the power supply to connection terminal 166 and LED 168 in response to a control signal from control device 170.

With such a structure, multiple tape feeders 70 are accommodated in tape feeder rack 150, and the information related to the types of the electronic components accommodated in multiple tape feeders 70 is managed in control device 170. Specifically, in a case where the operator wants to accommodate tape feeder 70 in tape feeder rack 150, the operator first inputs identification information (hereinafter referred to as “component ID”) indicating the type of electronic component 76 of taped component 72 set in tape feeder 70 to control device 170. When the operator inputs the component ID to control device 170, control device 170 specifies slide groove 160 in which tape feeder 70 is not accommodated, and outputs a control signal to supply the power to connection terminal 166 and LED 168 corresponding to slide groove 160 to power source 178. Therefore, power source 178 supplies the power to power supply cable 177 connected to connection terminal 166 and LED 168 corresponding to the control signal. As a result, in tape feeder rack 150, LED 168 is turned on as illustrated in FIG. 5. As will be described later, in control device 170, information indicating the accommodation position of tape feeder 70 accommodated in tape feeder rack 150, that is, the position of slide groove 160 in which the tape feeder is accommodated or an address or a number of the slide groove is stored in memory 176, so that control device 170 can specify slide groove 160 in which tape feeder 70 is not accommodated.

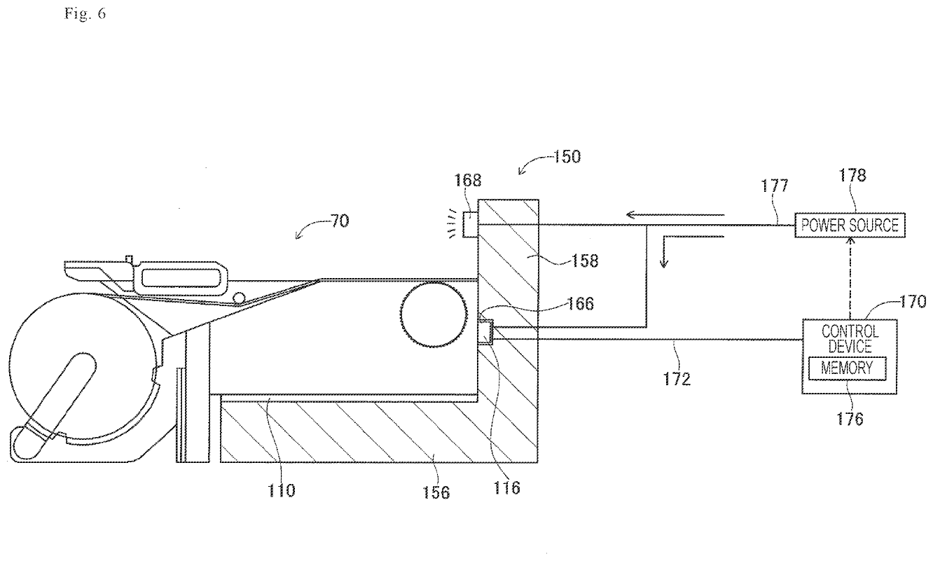

When LED 168 is turned on in tape feeder rack 150, the operator accommodates tape feeder 70 in slide groove 160 corresponding to LED 168 which is turned on, as illustrated in FIG. 6. That is, by fitting rail 110 of tape feeder 70 into slide groove 160 corresponding to LED 168 which is turned on and sliding rail 110 in a direction approaching rack side frame 158, connector 116 of tape feeder 70 is connected to connection terminal 166. As described above, when tape feeder 70 is accommodated in slide groove 160 corresponding to LED 168 which is turned on, since the power is supplied to connection terminal 166 corresponding to slide groove 160 together with LED 168 which is turned on, the power is supplied to tape feeder 70 mounted in slide groove 160.

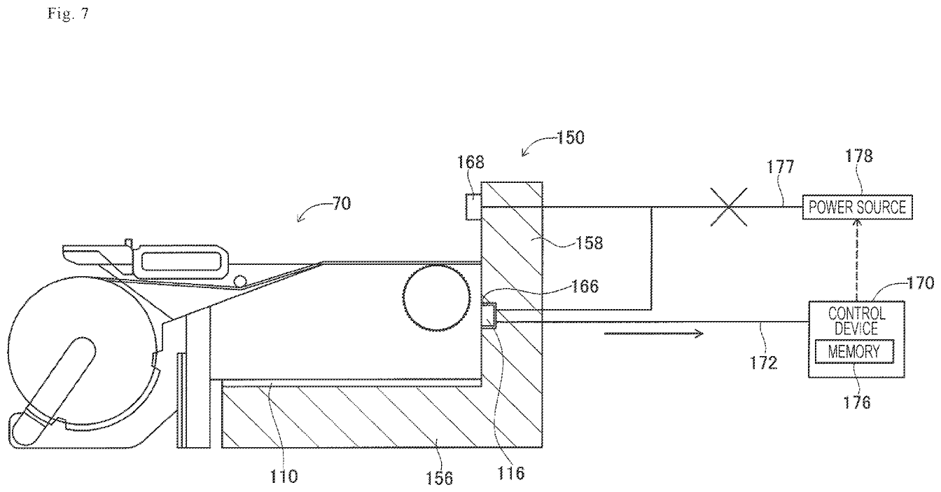

Next, when connector 116 is connected to connection terminal 166 and the power is supplied to tape feeder 70, as illustrated in FIG. 7, tape feeder 70 outputs its own identification information, that is, identification information of tape feeder 70 (hereinafter, referred to as “feeder ID”) to control device 170 through communication cable 172. Tape feeder 70 stores its own feeder ID. When the feeder ID is received, control device 170 determines that a normal tape feeder is mounted in slide groove 160 corresponding to connection terminal 166 and LED 168 to which the power is supplied. That is, when control device 170 receives the feeder ID of the mounted tape feeder, the control device recognizes that connector 116 of the tape feeder is connected to connection terminal 166 of slide groove 160 corresponding to LED 168 which is turned on, and thus determines that the normal tape feeder is mounted in slide groove 160 corresponding to connection terminal 166 and LED 168 to which the power is supplied.

Subsequently, when control device 170 determines that the normal tape feeder is mounted in slide groove 160, control device 170 outputs a control signal to cut off the power supply to connection terminal 166 and LED 168 corresponding to slide groove 160 to power source 178. Therefore, power source 178 cuts off the power supply to power supply cable 177 connected to connection terminal 166 and LED 168 corresponding to the control signal. As a result, in tape feeder rack 150, LED 168 corresponding to slide groove 160 in which the tape feeder is accommodated is turned off. As a result, the accommodation of the tape feeder in slide groove 160 is completed. Although the power supply to the tape feeder accommodated in slide groove 160 is cut off together with LED 168, it is not necessary to supply the power for operating the tape feeder to the tape feeder accommodated in slide groove 160 of the tape feeder rack.

When control device 170 receives the feeder ID through communication cable 172, control device 170 stores, in memory 176, identification information (hereinafter, referred to as “accommodation position ID”) of slide groove 160 corresponding to connection terminal 166 to which communication cable 172 is connected, the previously input component ID, and the feeder ID received through communication cable 172 in association with each other. That is, the accommodation position ID of slide groove 160 in which the tape feeder is accommodated, the feeder ID of tape feeder 70 accommodated in slide groove 160, and the component ID of the electronic component set in tape feeder 70 are stored in association with each other in memory 176. As described above, only by accommodating tape feeder 70 in slide groove 160 corresponding to LED 168, which is turned on, of tape feeder rack 150, in control device 170, the tape feeder (feeder ID) accommodated in tape feeder rack 150, the accommodation position (accommodation position ID) of the tape feeder, and the type (component ID) of the electronic component set in the tape feeder are managed in association with each other.

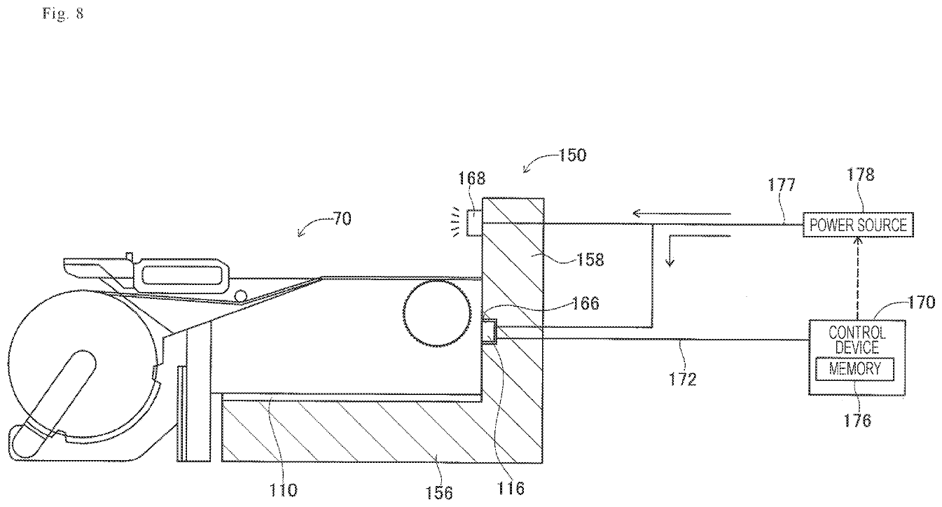

In addition, in a case where a new type of electronic component is necessary in the mounting operation of the electronic component in mounter 16, it is possible to easily extract the tape feeder in which taped component 72 of the newly necessary type of electronic component is set from tape feeder rack 150. Specifically, the operator inputs the component ID of the type of the electronic component which is newly necessary in the mounting operation of the electronic component in mounter 16 to control device 170. When the component ID is input to control device 170, control device 170 specifies the input component ID from among the component IDs stored in memory 176. Then, control device 170 extracts the accommodation position ID stored in memory 176 in association with the specified component ID. Subsequently, control device 170 outputs, to power source 178, a control signal to supply the power to connection terminal 166 and LED 168 corresponding to slide groove 160 identified by the extracted accommodation position ID. Therefore, power source 178 supplies the power to power supply cable 177 connected to connection terminal 166 and LED 168 corresponding to the control signal. As a result, in tape feeder rack 150, LED 168 is turned on as illustrated in FIG. 8. Then, the operator slides the tape feeder accommodated in slide groove 160 corresponding to LED 168 which is turned on in a direction separating from rack side frame 158, thereby extracting the tape feeder from tape feeder rack 150. As a result, the operator can easily select and extract the tape feeder in which taped component 72 of the newly necessary type of electronic component is set from tape feeder rack 150. Then, the operator mounts the tape feeder extracted from tape feeder rack 150 on tape feeder holding table 100 of mounter 16, whereby the mounting operation of the new electronic component is executed in mounter 16.

As described above, by using the information managed in control device 170, the tape feeder in which taped component 72 of the necessary type of electronic component is set can be easily selected and extracted from tape feeder rack 150 only by inputting the component ID of the necessary type of electronic component to control device 170. Further, in tape feeder rack 150, one bifurcated power supply cable 177 is connected to connection terminal 166 and LED 168 corresponding to each of multiple slide grooves 160, and the power is supplied from power source 178 through one power supply cable 177, so that cost reduction and simplification of the structure are achieved. Specifically, in the conventional tape feeder rack, it is necessary to prepare a terminal cable for always supplying the power to connection terminal 166 corresponding to each of multiple slide grooves 160 and a remote IO module (control board) for turning on and off LED 168 corresponding to each of multiple slide grooves 160. That is, it is necessary to prepare multiple terminal cables corresponding to multiple connection terminals 166 and multiple remote IO modules corresponding to multiple LEDs 168. As described above, in a case where multiple terminal cables and multiple remote IO modules are disposed in the tape feeder rack, the cost increases, and the structure of the tape feeder rack is also complicated. Meanwhile, since it is not necessary to supply the power to the tape feeder accommodated in the tape feeder rack, in tape feeder rack 150, one bifurcated power supply cable 177 is connected to connection terminal 166 and LED 168 corresponding to each of multiple slide grooves 160, and the power is supplied from power source 178 through one power supply cable 177. That is, one power supply cable 177 functions as a cable for supplying the power to the tape feeder mounted on tape feeder rack 150 and an output IO to LED 168. As a result, cost reduction and simplification of the structure are achieved in tape feeder rack 150.

Tape feeder 70 is an example of a feeder. Slide groove 160 is an example of a slot. LED 168 is an example of an indicator lamp. Control device 170 is an example of a control device.

The present disclosure is not limited to the example described above, and can be performed in various aspects to which various modifications and improvements are applied based on the knowledge of those skilled in the art. Specifically, for example, in the example described above, the power is supplied to LED 168 corresponding to each of multiple slide grooves 160 through power supply cable 177 that supplies the power to connection terminal 166 corresponding to each of multiple slide grooves 160, and LED 168 is turned on. Meanwhile, LED 168 corresponding to each of multiple slide grooves 160 may be turned on by supplying the power to LED 168 through a cable different from power supply cable 177 that supplies the power to connection terminal 166 corresponding to each of multiple slide grooves 160. That is, the power may be supplied to connection terminal 166 through the power supply cable for the connection terminal, and the power may be supplied to LED 168 through the power supply cable for the LED. As described above, in a case where the power is supplied to connection terminal 166 from the power supply cable for the connection terminal and the power is supplied to LED 168 from the power supply cable for the LED, for example, even when the power supply to connection terminal 166 is cut off, the power supply to LED 168 may be maintained without cutting off the power supply to LED 168. That is, when the power supply to connection terminal 166 is cut off, the power supply to LED 168 may be maintained and the turned on state of LED 168 may be maintained. In a case where the power is supplied to connection terminal 166 from the power supply cable for the connection terminal and the power is supplied to LED 168 from the power supply cable for the LED, for example, even when the power supply to LED 168 is cut off and LED 168 is turned off, the power supply to connection terminal 166 may be maintained without cutting off the power supply to connection terminal 166.

In the example described above, control device 170 determines that the normal tape feeder is accommodated in slide groove 160 in a case where control device 170 receives the feeder ID, but control device 170 may determine that the normal tape feeder is accommodated in slide groove 160 in a case where the feeder ID received by control device 170 matches ID set in advance. In addition, control device 170 may determine that the normal tape feeder is accommodated in slide groove 160 in a case where control device 170 receives other information, for example, information indicating that connector 116 of the tape feeder is connected to connection terminal 166 without being limited to the feeder ID.

In the example described above, the power is supplied to the tape feeder accommodated in slide groove 160 through connector 116, but the power may be supplied to the tape feeder through rail 110 of the tape feeder. In addition, the power may be supplied from the tape feeder rack to the tape feeder without contact with the tape feeder accommodated in slide groove 160.

In the example described above, the component ID of the electronic component is input to control device 170 by the operator, but the component ID of the electronic component may be input to the tape feeder. As described above, in a case where the component ID is input to the tape feeder, when the tape feeder is accommodated in tape feeder rack 150, the component ID and the feeder ID are output from the tape feeder accommodated in tape feeder rack 150 to control device 170 through communication cable 172.

In the example described above, the accommodation position ID, the feeder ID, and the component ID are stored in association with each other in memory 176 of control device 170, but the accommodation position ID, the feeder ID, and the component ID may be stored in association with each other in a device difference from control device 170, for example, a server, PC other than the control device, and the like. That is, when control device 170 receives the feeder ID from the tape feeder accommodated in tape feeder rack 150, control device 170 may output the feeder ID, the accommodation position ID, and the component ID to a server or the like, and the server or the like may store the feeder ID, the accommodation position ID, and the component ID in association with one another.

In the example described above, the tape feeder is accommodated in the tape feeder rack by fitting rail 110 of the tape feeder into slide groove 160, but the tape feeder can be accommodated in the tape feeder rack in various aspects as long as the tape feeder can be accommodated. For example, the tape feeder can be accommodated in the tape feeder rack by forming a rail, a recessed portion, a holder, or the like in the feeder rack and holding the tape feeder by the rail, the recessed portion, the holder, or the like. In the example described above, the tape feeder is accommodated in the tape feeder rack in a positioned state, but the tape feeder may be accommodated in the tape feeder rack without being positioned. Further, in the example described above, the tape feeder is positioned and accommodated in the tape feeder rack by one touch by the operator without using a tool, but the tape feeder may be accommodated in the tape feeder rack by using a tool by the operator. Further, the tape feeder may be automatically accommodated in the tape feeder rack by using an articulated robot, a multi-axis robot, or the like.

Control device 170 connected to tape feeder rack 150 may be a control device that controls mounter 16, or may be a laptop computer, a 5G terminal, or the like connected to mounter 16.

In addition, tape feeder rack 150 may be disposed in the vicinity of mounter 16 in consideration of work efficiency of the operator, or may be disposed in, for example, a component warehouse separated from mounter 16.

Further, in the example described above, the tape feeder in which the taped component in which the electronic component is accommodated is set in each of multiple accommodation recessed portions 80 is adopted as the tape feeder accommodated in tape feeder rack 150, but a tape feeder in which a taped component in which various types of multiple lead components (axial lead components, radial lead components, and the like) are taped is set can be adopted. Further, the disclosure is not limited to the tape feeder in which the taped component is set, and various feeders, such as a bowl feeder, a stick feeder, and a bulk feeder, can be adopted.

### REFERENCE SIGNS LIST

70: tape feeder (feeder), 160: slide groove (slot), 168: LED (indicator lamp), 170: control device

1. A control device configured to supply power to multiple slots each of which includes an indicator lamp and into which feeders are inserted, and to turn on the indicator lamp of the slot to which the power is supplied.

2. The control device according to claim 1,
wherein the control device is configured to, in a case where a normal feeder is inserted into the slot to which the power is supplied, cut off the supply of the power to the slot to which the power is supplied.

3. The control device according to claim 1,
wherein the control device is configured to, in a case where a normal feeder is inserted into the slot to which the power is supplied, turn off the indicator lamp of the slot to which the power is supplied.

4. A method for supplying power to feeders inserted from multiple slots each of which includes an indicator lamp and into which the feeders are inserted, the method comprising:
a feeder insertion position indication step of turning on an indicator lamp of a slot to which the power is supplied;
a feeder insertion step of inserting the feeder into the slot to which the power is supplied and of which the indicator lamp is turned on in the feeder insertion position indication step; and
a power supply check step of, in a case where the feeder inserted in the feeder insertion step is a normal feeder, turning off the indicator lamp of the slot to which the power is supplied, the indicator lamp being turned on by supplying the power to the inserted feeder.
